(19) United States
(12) Patent Application Publication
(10) Pub. No.: US 2026/0032892 A1
(43) Pub. Date: Jan. 29, 2026

(54) SEMICONDUCTOR DEVICE AND METHOD OF MANUFACTURING THE SAME

(71) Applicant: Samsung Electronics Co., Ltd., Suwon-si (KR)

(72) Inventors: IN-JAE BAE, Suwon-si (KR); JAEJOON SONG, Suwon-si (KR); CHANGSIK YOO, Suwon-si (KR)

(21) Appl. No.: 19/033,829

(22) Filed: Jan. 22, 2025

(30) Foreign Application Priority Data
Jul. 29, 2024 (KR) 10-2024-0100043

(51) Int. Cl. H10B 12/00

(52) U.S. Cl. CPC H10B 12/488; H10B 12/03; H10B 12/053; H10B 12/482

(57) ABSTRACT

A semiconductor device includes at least one bit line extending in a first direction on a substrate, and at least one gate region on the at least one bit line. A first gate region may include a first channel layer extending in a second direction perpendicular to the first direction and extending in a third direction perpendicular to the substrate, a first word line on one side of the first channel layer, a first cover insulating layer on a first side surface of the first word line facing the first channel layer, and a second cover insulating layer on a second side surface of the first word line opposite the first side surface of the first word line. A thickness in the first direction of the first cover insulating layer may be less than a thickness in the first direction of the second cover insulating layer.

### CROSS-REFERENCE TO RELATED APPLICATION

This application claims the benefit of Korean Patent Application No. 10-2024-0100043, filed on Jul. 29, 2024, in the Korean Intellectual Property Office, the entire disclosure of which is incorporated herein by reference for all purposes.

### FIELD

The following embodiments relate to a semiconductor device and a method of manufacturing the semiconductor device, and more particularly, to a semiconductor device including a vertical channel transistor (VCT) and a method of manufacturing the semiconductor device.

### BACKGROUND

As the integration density of semiconductor memory devices gradually increases, the integration density of semiconductor devices included in semiconductor memory devices also increases. Since the integration density of two-dimensional (2D) or planar semiconductor memory devices is primarily determined by an area occupied by a unit memory cell, the integration density is significantly affected by the level of technology of forming fine patterns. However, costly equipment needed to increase pattern fineness may set a limitation on increasing the integration density of 2D semiconductor memory devices. Therefore, to increase the integration density of semiconductor devices, vertical channel transistors that are formed vertically on semiconductor substrates, instead of planar channel transistors that are formed planarly on semiconductor substrates, have been introduced.

### SUMMARY

One or more embodiments provide a semiconductor device and a method of manufacturing the semiconductor device that may prevent coupling between word lines.

Goals to be achieved by the present disclosure are not limited to those described above, and other goals not mentioned above can be clearly understood by one of ordinary skill in the art from the following description.

According to an embodiment, a semiconductor device includes at least one bit line extending in a first direction on a substrate, and at least one gate region on the at least one-bit line. A first gate region may include a first channel layer extending in a second direction perpendicular to the first direction and extending in a third direction perpendicular to the substrate, a first word line on a side of the first channel layer, a first cover insulating layer on a first side surface of the first word line facing the first channel layer, and a second cover insulating layer on a second side surface of the first word line opposite the first side surface of the first word line. A thickness in the first direction of the first cover insulating layer may be less than a thickness in the first direction of the second cover insulating layer.

A first permittivity of the first cover insulating layer may be different from a second permittivity of the second cover insulating layer.

The first permittivity may be greater than the second permittivity.

The first channel layer may be formed of silicon.

The first gate region may further include a first filling insulating layer between the first word line and the at least one bit line.

The semiconductor device may further include at least one silicon layer between the at least one gate region and the at least one bit line.

The first gate region may further include a second filling insulating layer on the first word line.

The semiconductor device may further include a second gate region on one side of the first gate region.

The second gate region may include a second channel layer in contact with the second cover insulating layer of the first gate region, a second word line on one side of the second channel layer, a third cover insulating layer on a first side surface of the second word line facing the second channel layer, and a fourth cover insulating layer on a second side surface of the second word line opposite the first side surface of the second word line. A thickness in the first direction of the third cover insulating layer may be less than a thickness of the fourth cover insulating layer.

A third permittivity of the third cover insulating layer may be greater than a second permittivity of the second cover insulating layer.

A first voltage applied to the first word line may be greater than a second voltage applied to the second word line. The first channel layer may be controlled to be in an active state, and the second channel layer may be controlled to be in an inactive state.

According to another aspect, a semiconductor device includes a plurality of bit lines extending in a first direction on a substrate, a plurality of gate isolation insulating layers that extend in a second direction perpendicular to the first direction on the plurality of bit lines and that extends in a third direction perpendicular to the substrate, and a plurality of gate regions, each of the gate regions being between gate isolation insulating layers spaced apart from each other.

A first gate region may include a first channel layer extending along a side surface of one of the plurality of gate isolation insulating layers on two sides of the first gate region and on a top surface of a bit line being under the first gate region, a first word line between a first and a second side surface of the first channel layer facing each other, a first cover insulating layer between another side surface of the first word line and another side surface of the first channel layer, and a second cover insulating layer between a second side surface of the first word line and a second side surface of the first channel layer. A thickness of the first cover insulating layer may be less than a thickness of the second cover insulating layer.

A first permittivity of the first cover insulating layer may be different from a second permittivity of the second cover insulating layer.

The first permittivity may be greater than the second permittivity.

The first gate region may further include a first filling insulating layer on the first word line.

The first channel layer may include an oxide semiconductor.

According to another aspect, a method of manufacturing a semiconductor device includes forming a bit line extending in a first direction on a substrate, forming a plurality of channel layers that extend in a second direction perpendicular to the first direction on the bit line and in a third direction perpendicular to the substrate, forming a first cover insulating layer between the plurality of channel layers, forming a word line between sidewalls of the first cover insulating layers, and forming a second cover insulating layer on an exposed sidewall of the word line after removing a portion of the first cover insulating layer on one side of the word line and removing a portion of the word line. A thickness in the first direction of the first cover insulating layer may be less than a thickness in the first direction of the second cover insulating layer.

The forming of the plurality of channel layers may include forming a plurality of channel layers, each having one end in contact with the bit line and forming a first filling insulating layer between channel layers spaced apart from each other, wherein a height of the first filling insulating layer is less than a height of one of the plurality of channel layers with respect to the substrate.

The forming of the first cover insulating layer may include forming an initial first cover insulating layer that extends along a side surface of each of the channel layers and a top surface of the first filling insulating layer disposed between channel layers, and etching the initial first cover insulating layer directly on the top surface of the first filling insulating layer and the first cover insulating layer directly on a top surface of each of the channel layers to form the first cover insulating layer.

The forming of the second cover insulating layer may include forming a sacrificial pattern layer configured to at least partially cover a top surface of the first cover insulating layer, a top surface of the word line, and the top surface of at least one of the plurality of the channel layers, etching one portion of the first cover insulating layer and one portion of the word line, removing the sacrificial pattern layer, and forming a second cover insulating layer in a space formed by removing the one portion of the first cover insulating layer and the one portion of the word line. A first permittivity of the first cover insulating layer may be greater than a second permittivity of the second cover insulating layer.

The method may further include forming a second filling insulating layer on the word line.

Additional aspects of embodiments will be set forth in part in the description which follows and, in part, will be apparent from the description, or may be learned by practice of the disclosure.

According to embodiments, a semiconductor device and a method of manufacturing the semiconductor device may effectively prevent coupling between word lines.

According to embodiments, a semiconductor device and a method of manufacturing the semiconductor device may enhance electrical characteristics and reliability of the semiconductor device.

Effects according to the disclosure are not limited to those mentioned above, and other effects that have not been mentioned can be clearly understood by one of ordinary skill in the art from the following description.

### BRIEF DESCRIPTION OF THE DRAWINGS

These and/or other aspects, features, and advantages of the invention will become apparent and more readily appreciated from the following description of embodiments, taken in conjunction with the accompanying drawings of which:

FIG. 1 is a block diagram illustrating a semiconductor memory device with a semiconductor device according to an embodiment;

FIG. 2 is a circuit diagram schematically illustrating a semiconductor memory device with a semiconductor device according to an embodiment;

FIG. 3 is a layout diagram illustrating an example of a semiconductor device according to an embodiment;

FIGS. 4 to 6 are cross-sectional views illustrating the semiconductor device of FIG. 3, taken along line I-I′ of FIG. 3;

FIG. 7 is a layout diagram illustrating another example of a semiconductor device according to an embodiment;

FIGS. 8 to 10 are cross-sectional views illustrating the semiconductor device of FIG. 7, taken along line J-J′ of FIG. 7;

FIG. 11 is a layout diagram illustrating another example of a semiconductor device according to an embodiment;

FIG. 12 is a cross-sectional view illustrating the semiconductor device of FIG. 11, taken along line K-K′ of FIG. 11;

FIG. 13 is a flowchart illustrating a method of manufacturing a semiconductor device according to an embodiment; and

FIGS. 14 to 22 are cross-sectional views to describe a method of manufacturing a semiconductor device according to an embodiment.

### DETAILED DESCRIPTION

Hereinafter, embodiments will be described in detail with reference to the accompanying drawings. However, various alterations and modifications may be made to the embodiments. Here, the embodiments are not construed as limited to the disclosure. The embodiments should be understood to include all changes, equivalents, and replacements within the idea and the technical scope of the disclosure.

The terminology used herein is for the purpose of describing particular embodiments only and is not to be limiting of the embodiments. The singular forms “a”, “an”, and “the” are intended to include the plural forms as well, unless the context clearly indicates otherwise. It will be further understood that the terms “comprises/including” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical and scientific terms used herein have the same meaning as commonly understood by one of ordinary skill in the art to which embodiments belong. Terms, such as those defined in commonly used dictionaries, are to be interpreted as having a meaning that is consistent with their meaning in the context of the relevant art and the present disclosure and are not to be interpreted in an idealized or overly formal sense unless expressly so defined herein.

When describing the embodiments with reference to the accompanying drawings, like reference numerals refer to like components and a repeated description related thereto will be omitted. In the description of embodiments, detailed description of well-known related structures or functions will be omitted when it is deemed that such description will cause ambiguous interpretation of the present disclosure. As used herein, notation such as (1-1)-th refers to a first element in a first group of elements, (1-2)-th refers to a second element in a first group of elements, (2-1)-th refers to a first element in a second group of elements, and so forth.

In addition, terms such as first, second, A, B, (a), (b), and the like may be used to describe components of the embodiments. Each of these terms is not used to define an essence, order or sequence of a corresponding component but used merely to distinguish the corresponding component from other component(s). It should be noted that if it is described in the specification that one component is “connected”, “coupled” or “joined” to another component, the former may be directly “connected”, “coupled”, and “joined” to the latter or “connected”, “coupled”, and “joined” to the latter via another component.

A component, which has the same common function as the component included in one embodiment, will be described by using the same name in other embodiments. Unless disclosed to the contrary, the description of any one embodiment may be applied to other embodiments, and the specific description of the repeated configuration will be omitted.

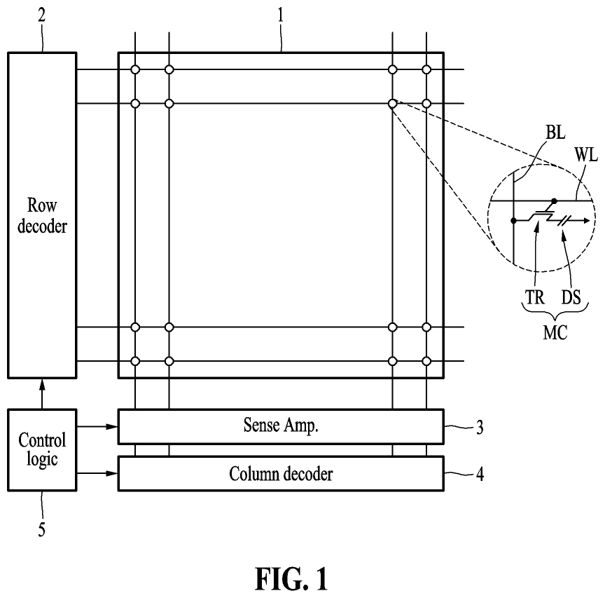

FIG. 1 is a block diagram illustrating a semiconductor memory device with a semiconductor device according to an embodiment.

Referring to FIG. 1, the semiconductor memory device may include a memory cell array 1, a row decoder 2, a sense amplifier 3, a column decoder 4, and a control logic 5. For example, the semiconductor memory device may be implemented as a dynamic random access memory (DRAM) device.

The memory cell array 1 may include a plurality of memory cells MC that are two-dimensionally or three-dimensionally arranged. For example, the memory cell array 1 may be disposed on one surface of a substrate, and a plane of the memory cell array 1 may be parallel to a plane of the substrate. Each of the memory cells MC may be connected to a word line WL and a bit line BL that cross each other.

Each of the memory cells MC may include a selection element TR and a data storage element DS. The selection element TR and the data storage element DS may be electrically connected. The selection element TR may be connected to both the word line WL and the bit line BL. For example, the selection element TR may be provided at a position in which the word line WL and the bit line BL cross each other. The selection element TR may include, for example, a field effect transistor (FET). The data storage element DS may include, for example, a capacitor, a magnetic tunnel junction pattern, or a variable resistor. For example, the selection element TR may be a transistor, and the transistor may include a gate electrode that is connected the word line WL, and a source terminal or a drain terminal that is connected to the bit line BL or the data storage element DS.

A selection element TR of each of the memory cells MC may include a vertical channel transistor (VCT). A lengthwise direction of a channel of the vertical channel transistor (VCT) may be perpendicular to one surface (e.g., a top surface) of the substrate. A data storage element DS of each of the memory cells MC may include a data storage pattern DSP.

The row decoder 2 may decode an address that is input from the outside of the semiconductor memory device. The row decoder 2 may select one of word lines WL of the memory cell array 1, based on a result obtained by decoding the address. The result (e.g., the decoded address) obtained by decoding the address in the row decoder 2 may be provided to a row driver (not shown). The row driver may separately provide predetermined voltages to the selected word line WL and unselected word lines, in response to controls of control circuits.

The sense amplifier 3 may sense, amplify, and output a difference in voltage between a reference bit line and a bit line BL that is selected based on an address decoded by the column decoder 4.

The column decoder 4 may provide a data transmission path between the sense amplifier 3 and an external device (e.g., a memory controller). The column decoder 4 may decode an externally input address to select one of bit lines BL.

The control logic 5 may generate a control signal that is used to control an operation of writing or reading data to or from a corresponding memory cell in the memory cell array 1.

For reference, the row decoder 2, the sense amplifier 3, the column decoder 4, and the control logic 5 are illustrated around the memory cell array 1, however, embodiments are not limited thereto. For example, a peripheral circuit including the row decoder 2, the sense amplifier 3, the column decoder 4, and the control logic 5 may be disposed on a plane different from a plane on which the memory cell array 1 is disposed. The peripheral circuit may be disposed above or below the memory cell array 1, using a cell over peripheral (COP) structure. In an example, the peripheral circuit may be provided on the substrate, and the memory cell array 1 may be provided on the peripheral circuit. In another example, the peripheral circuit may be provided on a first substrate, and the memory cell array 1 may be provided on a second substrate. In this example, the first substrate and the second substrate may face each other.

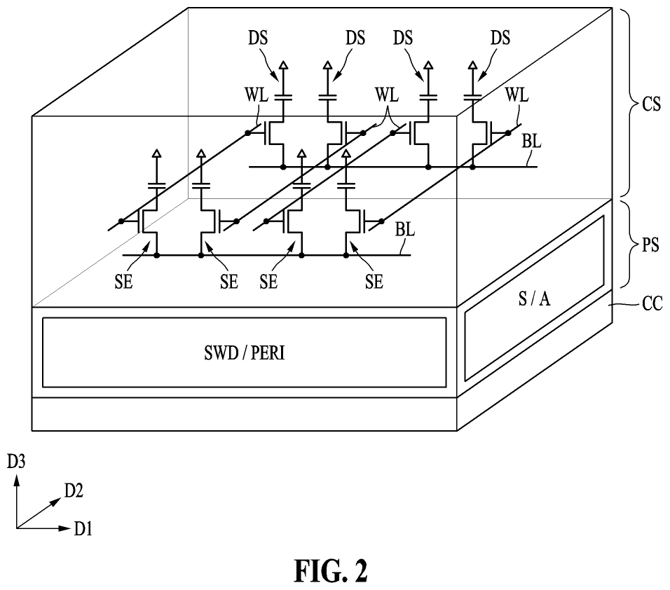

FIG. 2 is a circuit diagram schematically illustrating a semiconductor memory device with a semiconductor device according to an embodiment.

Referring to FIG. 2, the semiconductor memory device with the semiconductor device may include a peripheral circuit structure PS on a substrate CC, and a cell array structure CS on the peripheral circuit structure PS.

The peripheral circuit structure PS may include core and peripheral circuits that are formed on the substrate CC. The core and peripheral circuits may include the row decoder 2, the column decoder 4, the sense amplifier 3, and the control logic 5 described with reference to FIG. 1. The peripheral circuit structure PS may be provided between the substrate CC and the cell array structure CS in a third direction D3 perpendicular to a top surface of the substrate CC.

For reference, the first direction D1 and the second direction D2 may be directions parallel to the top surface of the substrate CC and perpendicular to each other. The third direction D3 may be a direction perpendicular to the first direction D1 and the second direction D2.

The cell array structure CS may include a bit line BL, a word line WL, and memory cells (e.g., the memory cells MC of FIG. 1) between the bit line BL and the word line WL. The memory cells (e.g., the memory cells MC of FIG. 1) may be two-dimensionally or three-dimensionally arranged on a plane parallel to the top surface of the substrate CC and extending in the first direction D1 and the second direction D2 that cross each other. Each of the memory cells (e.g., the memory cells MC of FIG. 1) may include a selection element SE and a data storage element DS, as described above.

Each of the memory cells (e.g., the memory cells MC of FIG. 1) may include a vertical channel transistor (VCT) as a selection element SE. The vertical channel transistor may be a structure in which a channel extends in a direction (i.e., the third direction D3) perpendicular to the top surface of the substrate CC. In addition, each of the memory cells (e.g., the memory cells MC of FIG. 1) may include a capacitor as a data storage element DS.

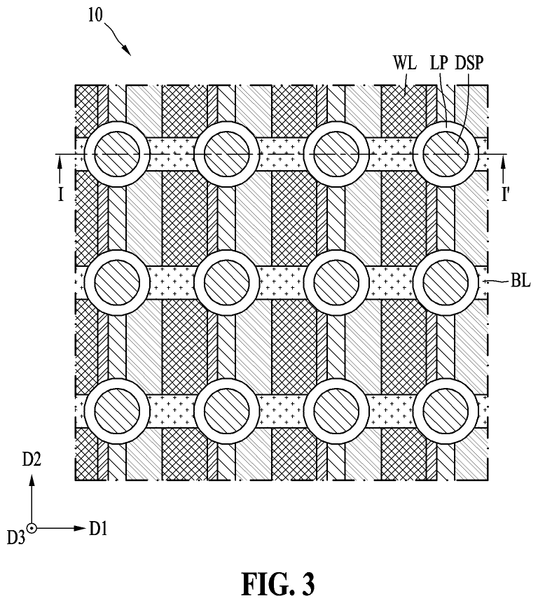

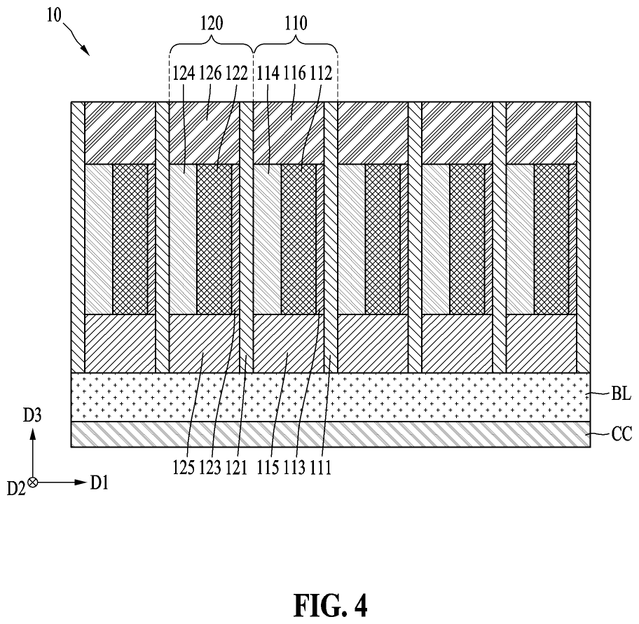

FIG. 3 is a layout diagram illustrating an example of a semiconductor device according to an embodiment. FIGS. 4 to 6 are cross-sectional views illustrating the semiconductor device of FIG. 3, taken along line I-I′ of FIG. 3.

The semiconductor device according to an embodiment may include memory cells that include a vertical channel transistor (VCT).

Referring to FIGS. 3 and 4, a semiconductor device 10 may include at least one bit line BL, and at least one gate region, for example, a first gate region 110 and a second gate region 120. The at least one bit line BL may extend in a first direction D1 on a substrate CC. The at least one gate region (e.g., the first gate region 110 and the second gate region 120) may be disposed on the at least one bit line BL.

The substrate CC may extend in the first direction D1 and a second direction D2. The first direction D1 and the second direction D2 may cross each other and may be parallel to a top surface of the substrate CC. The substrate CC may be a semiconductor substrate. The substrate CC may be a silicon substrate. Alternatively, the substrate CC may include other materials, such as silicon germanium, indium antimonide, lead telluride compound, indium arsenide, indium phosphide, gallium arsenide, or gallium antimonide, but is not limited thereto.

The bit line BL may be disposed on the substrate CC. The bit line BL may extend lengthwise in the first direction D1. For example, a plurality of bit lines BL may be provided and spaced apart from each other in the second direction D2.

The bit line BL may include, for example, at least one of doped polysilicon, a metal (e.g., Al, Cu, Ti, Ta, Ru, W, Mo, Pt, Ni, or Co), a conductive metal nitride (e.g., TiN, TaN, WN, NbN, TiAlN, TiSiN, TaSIN, or RuTiN), a conductive metal silicide, or a conductive metal oxide (e.g., PtO, RuO₂, IrO₂, SrRuO₃ (SRO), (Ba,Sr)RuO₃ (BSRO), CaRuO₃ (CRO), or LSCo), but is not limited thereto. The bit line BL may include a single layer or multiple layers including the above-described materials. The bit line BL may include a two-dimensional (2D) semiconductor material. For example, the 2D semiconductor material may include graphene, a carbon nanotube, or a combination thereof.

A space between bit lines BL may be filled with a bit line isolation insulating layer (not shown). The bit line isolation insulating layer may include at least one of a silicon oxide, a silicon oxynitride, or a high-k dielectric material having a dielectric constant greater than that of the silicon oxide. The high-k dielectric material may include, for example, a metal oxide or a metal oxynitride. The high-k dielectric material may include, for example, at least one of SiN, HfO₂, HfSiO, HfSiON, HfTaO, HfTiO, HfZrO, ZrO₂, or Al₂O₃, but is not limited thereto.

A data storage pattern DSP may be electrically connected to a channel layer, for example, a first channel layer 111 and a second channel layer 121, that will be described below. A landing pad LP may be disposed between the channel layer (e.g., the first channel layer 111 and the second channel layer 121) and the data storage pattern DSP.

Landing pads LP may have various shapes, for example, a circular shape, an elliptical shape, a rectangular shape, a square shape, a rhombus shape, or a hexagonal shape. The landing pads LP may include conductive materials. The landing pads LP may include, for example, at least one of doped polysilicon, a conductive metal nitride, a conductive metal silicon nitride, a metal carbonitride, a conductive metal silicide, a conductive metal oxide, a 2D material, a metal, or a metal alloy.

Data storage patterns DSP may be disposed on each of the landing pads LP, respectively. The data storage patterns DSP may be arranged in a form of a matrix in the second direction D2 and the first direction D1. The data storage patterns DSP may completely or partially overlap the landing pads LP in a third direction D3. The data storage patterns DSP may be in contact with all top surfaces of the landing pads LP or a portion of the top surfaces of the landing pads LP.

The data storage patterns DSP may be capacitors. The data storage patterns DSP may include capacitor dielectric films interposed between storage electrodes and a plate electrode. Here, the storage electrodes may be in contact with the landing pads LP. In a plan view, the storage electrodes may have various shapes, for example, a circular shape, an elliptical shape, a rectangular shape, a square shape, a rhombus shape, or a hexagonal shape.

Alternatively, the data storage patterns DSP may be variable resistance patterns that may be switched between two resistance states by electrical pulses applied to a memory element. For example, the data storage patterns DSP may include phase-change materials having crystalline states changing depending on an amount of current, perovskite compounds, transition metal oxide, magnetic materials, ferromagnetic materials, or an antiferromagnetic material.

The landing pads LP and the data storage patterns DSP are illustrated as being disposed above bit lines BL and word lines WL based on the third direction D3, however, embodiments are not necessarily limited thereto. The landing pads LP and the data storage patterns DSP may be disposed below the bit lines BL and the word lines WL based on the third direction D3, if necessary.

Each of the first gate region 110 and the second gate region 120 may extend in the second direction D2 crossing the first direction D1 on the bit lines BL. Each of the first gate region 110 and the second gate region 120 may stand in the third direction D3 perpendicular to the substrate CC. The third direction D3 may be a direction perpendicular to both the first direction D1 and the second direction D2. For example, a plurality of gate regions (e.g., the first gate region 110 and the second gate region 120) may be formed and disposed adjacent to each other.

The first gate region 110 may include the first channel layer 111, a first word line 112, a (1-1)-th cover insulating layer 113, a (1-2)-th cover insulating layer 114, a (1-1)-th filling insulating layer 115, and a (1-2)-th filling insulating layer 116.

The first channel layer 111 may extend in the second direction D2 crossing the first direction D1 and stand in the third direction D3 perpendicular to the substrate CC. The second channel layer 121 that will be described below may be spaced apart from the first channel layer 111 by a preset distance. A word line, a cover insulating layer, and a filling insulating layer that will be described below may be disposed between the first channel layer 111 and the second channel layer 121. One end of the first channel layer 111 may be in contact with the bit line BL. The first channel layer 111 may be formed of silicon. However, embodiments are not limited thereto.

The first word line 112 may be disposed on one side of the first channel layer 111. The first word line 112 may be disposed at a position spaced apart from the first channel layer 111 in the first direction D1. The first word line 112 may be disposed between the (1-1)-th cover insulating layer 113 and the (1-2)-th cover insulating layer 114 that will be described below. The first word line 112 may extend lengthwise in the second direction D2.

The first word line 112 may include at least one of doped polysilicon, a metal (e.g., Al, Cu, Ti, Ta, Ru, W, Mo, Pt, Ni, or Co), a conductive metal nitride (e.g., TiN, TaN, WN, NbN, TiAlN, TiSiN, TaSiN, or RuTiN), a conductive metal silicide, or a conductive metal oxide (e.g., PtO, RuO₂, IrO₂, SrRuO₃ (SRO), (Ba,Sr)RuO₃ (BSRO), CaRuO₃ (CRO), or LSCo), but is not limited thereto. The first word line 112 may include a single layer or multiple layers including the above-described materials. The first word line 112 may include a 2D semiconductor material. For example, the 2D semiconductor material may include graphene, a carbon nanotube, or a combination thereof.

The (1-1)-th cover insulating layer 113 may be disposed on another side surface of the first word line 112 facing the first channel layer 111. The (1-1)-th cover insulating layer 113 may be disposed between the first word line 112 and the first channel layer 111.

The (1-2)-th cover insulating layer 114 may be disposed on one side surface of the first word line 112 facing the other side portion of the first word line 112. The (1-2)-th cover insulating layer 114 may be disposed between the first word line 112 and the second channel layer 121 of the second gate region 120 that will be described below.

The (1-1)-th cover insulating layer 113 or the (1-2)-th cover insulating layer 114 may include a silicon oxide film, a silicon oxynitride film, a high-k dielectric insulating film having a dielectric constant greater than that of the silicon oxide film, or a combination thereof. The (1-1)-th cover insulating layer 113 or the (1-2)-th cover insulating layer 114 may also be formed of an aluminum oxide (ALO). However, embodiments are not necessarily limited thereto.

A thickness of the (1-1)-th cover insulating layer 113 in the first direction D1 may be less than a thickness of the (1-2)-th cover insulating layer 114 in the first direction D1. A (1-1)-th thickness of the (1-1)-th cover insulating layer 113 in the first direction D1 may be less than a (1-2)-th thickness of the (1-2)-th cover insulating layer 114 in the first direction D1. The (1-1)-th cover insulating layer 113 adjacent to the first channel layer 111 may be formed to be thinner than the (1-2)-th cover insulating layer 114 disposed further away from the first channel layer 111. However, embodiments are not limited thereto. The thickness of the (1-1)-th cover insulating layer 113 may be equal to the thickness of the (1-2)-th cover insulating layer 114 when a (1-1)-th permittivity of the (1-1)-th cover insulating layer 113 is significantly higher than a (1-2)-th permittivity of the (1-2)-th cover insulating layer 114, which will be described below.

The (1-1)-th permittivity of the (1-1)-th cover insulating layer 113 may be different from the (1-2)-th permittivity of the (1-2)-th cover insulating layer 114. The (1-1)-th permittivity may be greater than the (1-2)-th permittivity. The (1-1)-th cover insulating layer 113 may be formed of a material with a high permittivity, for example, a hafnium oxide (HFO). The (1-2)-th cover insulating layer 114 may be formed of a material with a relatively low permittivity. However, embodiments are not limited thereto. When the (1-1)-th thickness of the (1-1)-th cover insulating layer 113 is significantly less than the (1-2)-th thickness of the (1-2)-th cover insulating layer 114, the (1-1)-th permittivity of the (1-1)-th cover insulating layer 113 may be equal to the (1-2)-th permittivity of the (1-2)-th cover insulating layer 114.

The first gate region 110 may further include a (1-1)-th filling insulating layer 115 disposed between the first word line 112 and the at least one bit line BL, and a (1-2)-th filling insulating layer 116 disposed on the first word line 112.

The (1-1)-th filling insulating layer 115 or the (1-2)-th filling insulating layer 116 may include at least one of a silicon oxide, a silicon nitride, a silicon oxynitride, or a low-k dielectric material. However, embodiments are not limited thereto. The (1-1)-th filling insulating layer 115 and the (1-2)-th filling insulating layer 116 may be formed of the same materials or different materials.

A top surface of the (1-1)-th filling insulating layer 115 may be in contact with a bottom surface of the first word line 112, a bottom surface of the (1-1)-th cover insulating layer 113, and a bottom surface of the (1-2)-th cover insulating layer 114. A bottom surface of the (1-1)-th filling insulating layer 115 may be in contact with a top surface of the bit line BL.

A bottom surface of the (1-2)-th filling insulating layer 116 may be in contact with a top surface of the first word line 112, a top surface of the (1-1)-th cover insulating layer 113, and a top surface of the (1-2)-th cover insulating layer 114. A top surface of the (1-2)-th filling insulating layer 116 may be on the same plane as a top surface of the first channel layer 111.

The semiconductor device 10 may further include a second gate region 120 disposed on one side of the first gate region 110.

The second gate region 120 may include the second channel layer 121, a second word line 122, a (2-1)-th cover insulating layer 123, a (2-2)-th cover insulating layer 124, a (2-1)-th filling insulating layer 125, and a (2-2)-th filling insulating layer 126.

The second channel layer 121 may be disposed in contact with the (1-2)-th cover insulating layer 114 of the first gate region 110. The second word line 122 may be disposed on one side of the second channel layer 121. The (2-1)-th cover insulating layer 123 may be disposed on another side surface of the second word line 122 facing the second channel layer 121. The (2-2)-th cover insulating layer 124 may be disposed on one side surface of the second word line 122 facing the other side surface of the second word line 122. The (2-1)-th filling insulating layer 125 may be disposed between the second word line 122 and the at least one bit line BL. The (2-2)-th filling insulating layer 126 may be disposed on the second word line 122.

A thickness of the (2-1)-th cover insulating layer 123 may be less than a thickness of the (2-2)-th cover insulating layer 124. A (2-1)-th permittivity of the (2-1)-th cover insulating layer 123 may be greater than a (2-2)-th permittivity of the (2-2)-th cover insulating layer 124.

By a first voltage applied to the first word line 112, the first channel layer 111 may be controlled to be in an active state or an inactive state. By a second voltage applied to the second word line 122, the second channel layer 121 may be controlled to be in an active state or an inactive state.

The first voltage applied to the first word line 112 may be greater than the second voltage applied to the second word line 122. The first voltage may be greater than a preset voltage, and the second voltage may be less than the preset voltage. Here, the first channel layer 111 may be controlled to be in the active state, and the second channel layer 121 may be controlled to be in the inactive state.

When both the first voltage applied to the first word line 112 and the second voltage applied to the second word line 122 are greater than the preset voltage, both the first channel layer 111 and the second channel layer 121 may be controlled to be in the active state.

When both the first voltage applied to the first word line 112 and the second voltage applied to the second word line 122 are less than the preset voltage, both the first channel layer 111 and the second channel layer 121 may be controlled to be in the inactive state.

However, embodiments are not limited thereto, and a channel layer of each gate region may be controlled to be in the active state or the inactive state by applying various combinations of voltages to a word line of each gate region.

Additional gate regions that are identical or similar to the first gate region 110 or the second gate region 120 may be arranged adjacent to the first gate region 110 or the second gate region 120 in the first direction D1.

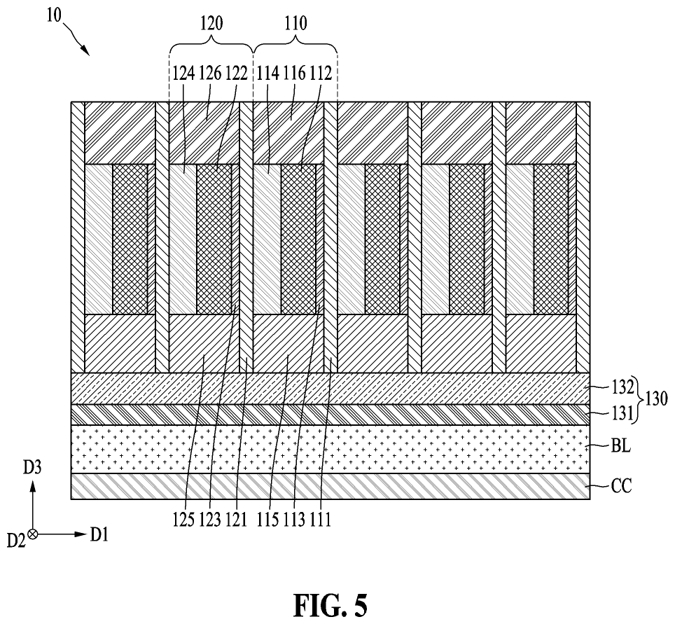

Referring to FIG. 5, the semiconductor device 10 may further include at least one silicon layer 130 disposed between the at least one gate region (e.g., the first gate region 110, and the second gate region 120) and the at least one bit line BL.

A first silicon layer 131 and a second silicon layer 132 may be disposed between the gate region (e.g., the first gate region 110, and the second gate region 120) and the bit line BL. The first silicon layer 131 may be disposed on the bit line BL. The second silicon layer 132 may be disposed on the first silicon layer 131. A bottom surface of a channel layer of each gate region may be in contact with a top surface of the second silicon layer 132.

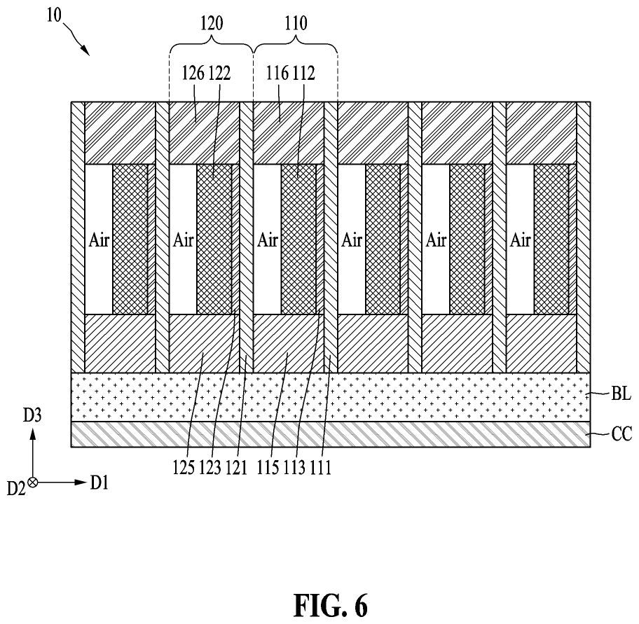

Referring to FIG. 6, a space in which the (1-2)-th cover insulating layer 114 of the first gate region 110 and the (2-2)-th cover insulating layer 124 of the second gate region 120 in the semiconductor device 10 are arranged may be replaced with air. Since air has a relatively extremely low permittivity, the permittivity of the air may be less than those of the (1-1)-th cover insulating layer 113 of the first gate region 110 and the (2-1)-th cover insulating layer 123 of the second gate region 120.

Hereinafter, repeated descriptions that may be equally applicable in the technical idea described above are omitted, and differences from various other embodiments are described.

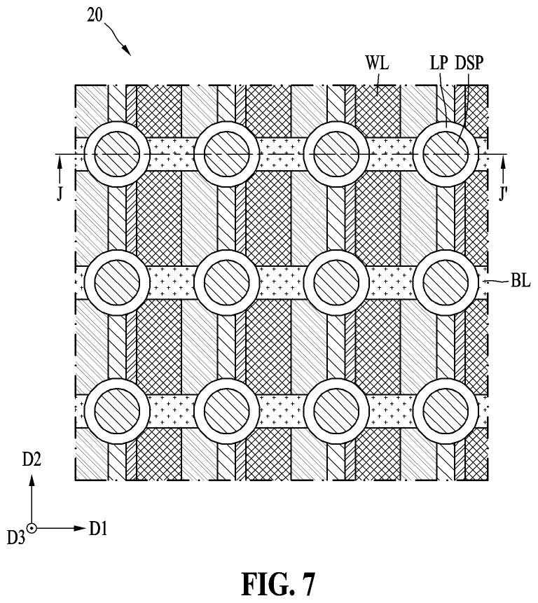

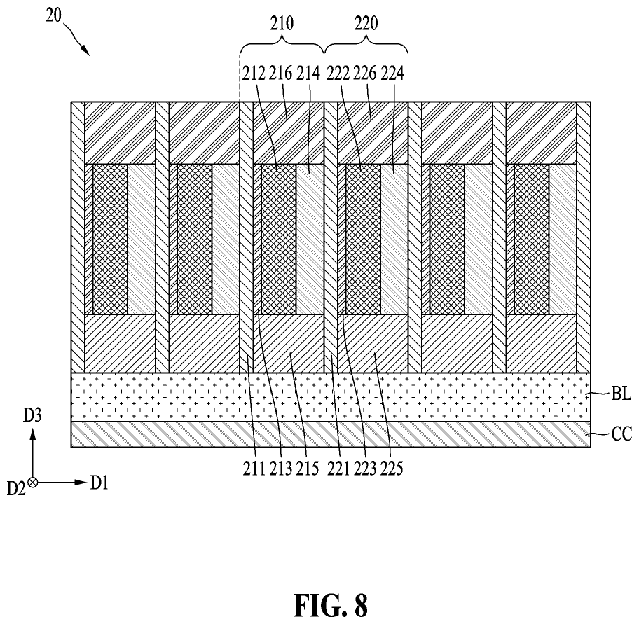

FIG. 7 is a layout diagram illustrating another example of a semiconductor device according to an embodiment. FIGS. 8 to 10 are cross-sectional views illustrating the semiconductor device of FIG. 7, taken along line J-J′ of FIG. 7.

Referring to FIGS. 7 and 8, a semiconductor device 20 may include at least one bit line BL and at least one gate region, for example, a first gate region 210 and a second gate region 220. The at least one bit line BL may extend in a first direction D1 on a substrate CC. The at least one gate region, for example, the first gate region 210 and the second gate region 220, may be disposed on the at least one bit line BL.

A data storage pattern DSP may be electrically connected to a channel layer, for example, a first channel layer 211 and a second channel layer 221, that will be described below. A landing pad LP may be disposed between the channel layer (e.g., the first channel layer 211 and the second channel layer 221) and the data storage pattern DSP.

The first gate region 210 may include the first channel layer 211, a first word line 212, a (1-1)-th cover insulating layer 213, a (1-2)-th cover insulating layer 214, a (1-1)-th filling insulating layer 215.

The first channel layer 211 may extend in a second direction D2 crossing the first direction D1 and stand in a third direction D3 perpendicular to the substrate CC. The first word line 212 may be disposed on another side of the first channel layer 211. The first word line 212 may be disposed at a position spaced apart from the first channel layer 211 in the first direction D1. The (1-1)-th cover insulating layer 213 may be disposed on one side surface of the first word line 212 facing the first channel layer 211. The (1-1)-th cover insulating layer 213 may be disposed between the first word line 212 and the first channel layer 211. The (1-2)-th cover insulating layer 214 may be disposed on another side surface of the first word line 212 facing the one side surface of the first word line 212. The (1-2)-th cover insulating layer 214 may be disposed between the first word line 212 and the second channel layer 221 of the second gate region 220 that will be described below.

A thickness of the (1-1)-th cover insulating layer 213 in the first direction D1 may be less than a thickness of the (1-2)-th cover insulating layer 214 in the first direction D1. A (1-1)-th permittivity of the (1-1)-th cover insulating layer 213 may be different from a (1-2)-th permittivity of the (1-2)-th cover insulating layer 214. The (1-1)-th permittivity may be greater than the (1-2)-th permittivity.

The first gate region 210 may further include a (1-1)-th filling insulating layer 215 disposed between the first word line 212 and the at least one bit line BL, and a (1-2)-th filling insulating layer 216 disposed on the first word line 212.

The semiconductor device 20 may further include the second gate region 220 disposed on another side of the first gate region 210.

The second gate region 220 may include the second channel layer 221, a second word line 222, a (2-1)-th cover insulating layer 223, a (2-2)-th cover insulating layer 224, a (2-1)-th filling insulating layer 225, and a (2-2)-th filling insulating layer 226.

The second channel layer 221 may be in contact with the (1-2)-th cover insulating layer 214 of the first gate region 210. The second word line 222 may be disposed on another side of the second channel layer 221. The (2-1)-th cover insulating layer 223 may be disposed on one side surface of the second word line 222 facing the second channel layer 221. The (2-2)-th cover insulating layer 224 may be disposed on another side surface of the second word line 122 facing the one side surface of the second word line 222. The (2-1)-th filling insulating layer 225 may be disposed between the second word line 222 and the at least one bit line BL. The (2-2)-th filling insulating layer 226 may be disposed on the second word line 222.

A thickness of the (2-1)-th cover insulating layer 223 may be less than a thickness of the (2-2)-th cover insulating layer 224. A (2-1)-th permittivity of the (2-1)-th cover insulating layer 223 may be greater than a (2-2)-th permittivity of the (2-2)-th cover insulating layer 224.

Additional gate regions that are identical or similar to the first gate region 210 or the second gate region 220 may be arranged adjacent to the first gate region 210 or the second gate region 220 in the first direction D1.

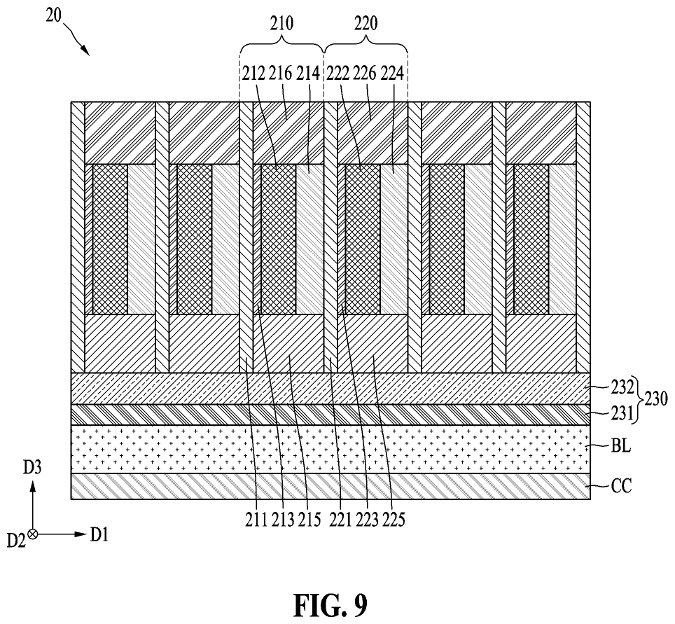

Referring to FIG. 9, the semiconductor device 20 may further include at least one silicon layer 230 disposed between the at least one gate region (e.g., the first gate region 210 and the second gate region 220) and the at least one bit line BL.

A first silicon layer 231 and a second silicon layer 232 may be disposed between the at least one gate region (e.g., the first gate region 210 and the second gate region 220) and the bit line BL. The first silicon layer 231 may be disposed on the bit line BL. The second silicon layer 232 may be disposed on the first silicon layer 231. A bottom surface of a channel layer of each gate region may be in contact with a top surface of the second silicon layer 232.

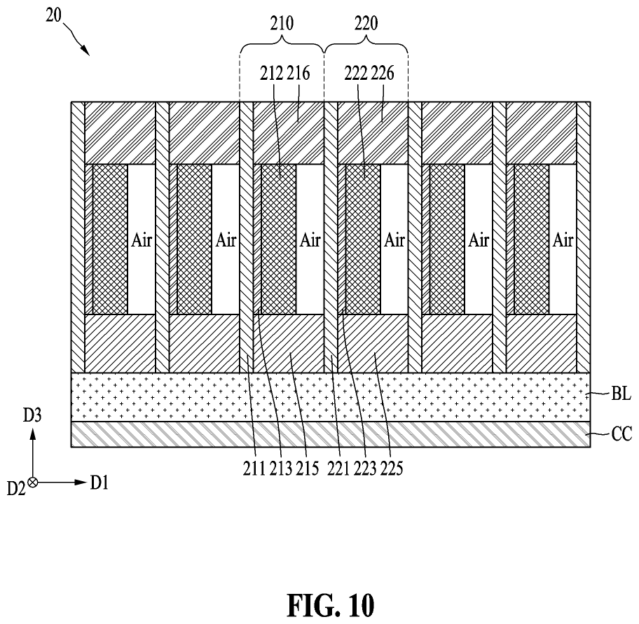

Referring to FIG. 10, a space in which the (1-2)-th cover insulating layer 214 of the first gate region 210 and the (2-2)-th cover insulating layer 224 of the second gate region 220 in the semiconductor device 20 are arranged may be replaced with air. Since air has a relatively extremely low permittivity, the permittivity of the air may be less than those of the (1-1)-th cover insulating layer 213 of the first gate region 210 and the (2-1)-th cover insulating layer 223 of the second gate region 220.

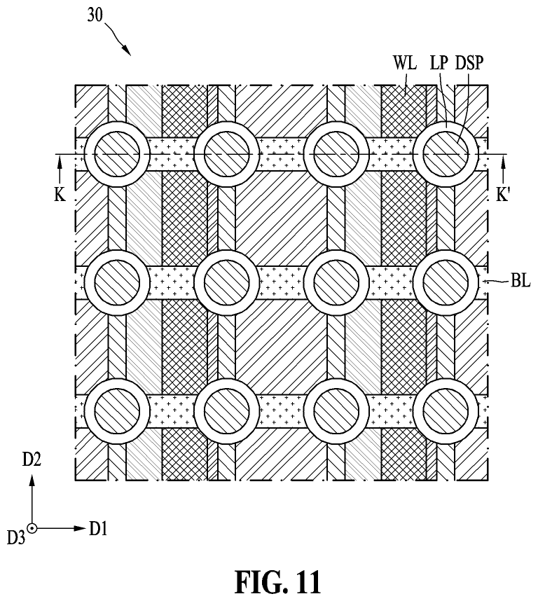

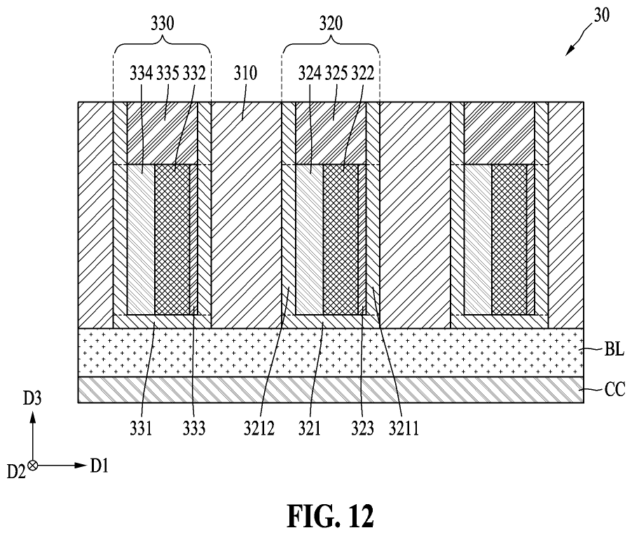

FIG. 11 is a layout diagram illustrating another example of a semiconductor device according to an embodiment. FIG. 12 is a cross-sectional view illustrating the semiconductor device of FIG. 11, taken along line K-K′ of FIG. 11.

Referring to FIGS. 11 and 12, a semiconductor device 30 may include a plurality of bit lines BL, a plurality of gate isolation insulating layers 310, and a plurality of gate regions, for example, a first gate region 320 and a second gate region 330. The plurality of bit lines BL may extend in a first direction D1 on a substrate CC. The plurality of gate isolation insulating layers 310 may extend in a second direction D2 crossing the first direction D1 on the plurality of bit lines BL and may stand in a third direction D3 perpendicular to the substrate CC. Each of the first gate region 320 and the second gate region 330 may be disposed between gate isolation insulating layers 310 spaced apart from each other.

A data storage pattern DSP may be electrically connected to a channel layer, for example, a first channel layer 321 and a second channel layer 331, that will be described below. A landing pad LP may be disposed between the channel layer (e.g., the first channel layer 321 and the second channel layer 331) and the data storage pattern DSP.

A gate isolation insulating layer 310 may include at least one of a silicon oxide, a silicon nitride, a silicon oxynitride, or a low-k dielectric material. However, embodiments are not limited thereto.

The first gate region 320 may include the first channel layer 321, a first word line 322, a (1-1)-th cover insulating layer 323, a (1-2)-th cover insulating layer 324, and a first filling insulating layer 325.

The first channel layer 321 may extend alongside surfaces of gate isolation insulating layers 310 disposed on both sides of the first gate region 320 and a top surface of the bit line BL being under the first gate region 320.

The first channel layer 321 may be formed of an oxide semiconductor. For example, the first channel layer 321 may include one of an indium gallium zinc oxide (IGZO), an indium zinc oxide (IZO) doped with impurities, an indium oxide (InO), a zinc oxide (ZnO), a gallium oxide (GaO), a tin oxide (SnO), an aluminum zinc oxide (AZO), and an indium tin oxide (ITO). In the IZO doped with impurities, the impurities may include, for example, at least one of magnesium (Mg), strontium (Sr), barium (Ba), scandium (Sc), yttrium (Y), lanthanum (La), titanium (Ti), zirconium (Zr), hafnium (Hf), aluminum (Al), tin (Sn), or tantalum (Ta). Indium (In), gallium (Ga), and zinc (Zn) may be included in the same or different amounts in the IGZO. The first channel layer 321 may be formed of a single layer or a plurality of layers, however, embodiments are not limited thereto.

The first word line 322 may be disposed between side surfaces of the first channel layer 321 facing each other. The first word line 322 may be disposed within the first channel layer 321 that defines the first gate region 320.

The (1-1)-th cover insulating layer 323 may be disposed between another side surface of the first word line 322 and another side surface of the first channel layer 321. The (1-1)-th cover insulating layer 323 may be disposed between the first word line 322 and another portion of the first channel layer 321 formed on the right based on the first direction D1.

The (1-2)-th cover insulating layer 324 may be disposed between one side surface of the first word line 322 and one side surface of the first channel layer 321. The (1-2)-th cover insulating layer 324 may be disposed between the first word line 322 and one portion of the first channel layer 321 formed on the left based on the first direction D1.

The one side surface of the first word line 322 may be in contact with the (1-2)-th cover insulating layer 324, and the other side surface of the first word line 322 may be in contact with the (1-1)-th cover insulating layer 323. The one portion of the first channel layer 321 may be in contact with the (1-2)-th cover insulating layer 324, and the other portion of the first channel layer 321 may be in contact with the (1-1)-th cover insulating layer 323.

A thickness of the (1-1)-th cover insulating layer 323 may be less than a thickness of the (1-2)-th cover insulating layer 324. A (1-1)-th permittivity of the (1-1)-th cover insulating layer 323 may be different from a (1-2)-th permittivity of the (1-2)-th cover insulating layer 324. The (1-1)-th permittivity may be greater than the (1-2)-th permittivity.

The first filling insulating layer 325 may be disposed on the first word line 322. A top surface of the first filling insulating layer 325 may be on the same plane as a top surface of the first channel layer 321.

In an example, by a first voltage applied to the first word line 322, the other portion of the first channel layer 321 in contact with the (1-1)-th cover insulating layer 323 may be controlled to be in an active state. In another example, by the first voltage applied to the first word line 322, the one portion of the first channel layer 321 in contact with the (1-2)-th cover insulating layer 324 may be controlled to be in an inactive state.

When a second voltage greater than the first voltage is applied to the first word line 322, both the other portion of the first channel layer 321 in contact with the (1-1)-th cover insulating layer 323 and the one portion of the first channel layer 321 in contact with the (1-2)-th cover insulating layer 324 may be controlled to be in the active state.

When a third voltage less than the first voltage is applied to the first word line 322, both the other portion of the first channel layer 321 in contact with the (1-1)-th cover insulating layer 323 and the one portion of the first channel layer 321 in contact with the (1-2)-th cover insulating layer 324 may be controlled to be in the inactive state.

The other portion of the first channel layer 321 in contact with the (1-1)-th cover insulating layer 323 may be defined as a first portion 3211 of the first channel layer 321. The one portion of the first channel layer 321 in contact with the (1-2)-th cover insulating layer 324 may be defined as a second portion 3212 of the first channel layer 321. The first portion 3211 and the second portion 3212 of the first channel layer 321 may independently operate.

Depending on a magnitude of a voltage applied to the first word line 322, each of the first portion 3211 and the second portion 3212 of the first channel layer 321 may be controlled to be in the active state or the inactive state. A gate isolation insulating layer 310 may be disposed adjacent to the first gate region 320. The second gate region 330 may be formed on one side surface of a gate isolation insulating layer 310 that faces another side surface of the gate isolation insulating layer 310 in contact with the first gate region 320.

The second gate region 330 may include the second channel layer 331, a second word line 332, a (2-1)-th cover insulating layer 333, a (2-2)-th cover insulating layer 334, and a second filling insulating layer 335.

The second channel layer 331 may extend alongside surfaces of gate isolation insulating layers 310 disposed on both sides of the second gate region 330 and a top surface of the bit line BL being under the second gate region 330.

The second word line 332 may be disposed between side surfaces of the second channel layer 331 facing each other. The (2-1)-th cover insulating layer 333 may be disposed between another side surface of the second word line 332 and another side surface of the second channel layer 331. The (2-2)-th cover insulating layer 334 may be disposed between one side surface of the second word line 332 and one side surface of the second channel layer 331. A thickness of the (2-1)-th cover insulating layer 333 may be less than a thickness of the (2-2)-th cover insulating layer 334. A (2-1)-th permittivity of the (2-1)-th cover insulating layer 333 may be different from a (2-2)-th permittivity of the (2-2)-th cover insulating layer 334. The (2-1)-th permittivity may be greater than the (2-2)-th permittivity.

The second filling insulating layer 335 may be disposed on the second word line 332.

By a fourth voltage applied to the second word line 332, another portion of the second channel layer 331 in contact with the (2-1)-th cover insulating layer 333 or one portion of the second channel layer 331 in contact with the (2-2)-th cover insulating layer 334 may be controlled to be in an active state or an inactive state.

Due to the gate isolation insulating layer 310 disposed between the first gate region 320 and the second gate region 330, the fourth voltage applied to the second word line 332 may not have an influence on the first channel layer 321 of the first gate region 320. In addition, the first voltage to the third voltage applied to the first word line 322 may not have an influence on the second channel layer 331 of the second gate region 330.

Additional gate regions that are identical or similar to the first gate region 320 or the second gate region 330 may be arranged to be spaced apart from the first gate region 320 or the second gate region 330 in the first direction D1.

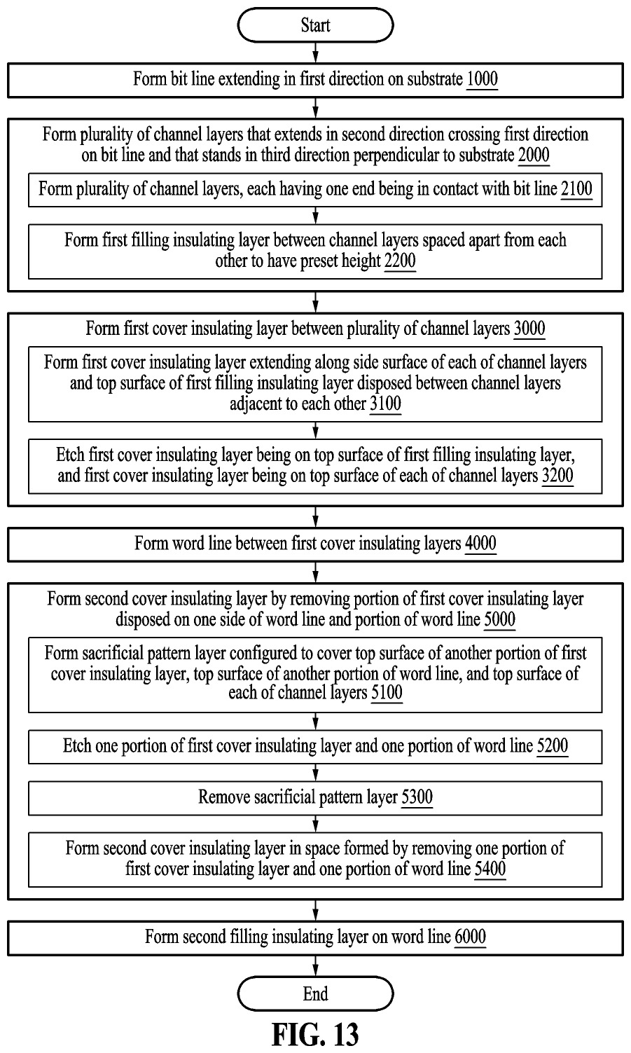

FIG. 13 is a flowchart illustrating a method of manufacturing a semiconductor device according to an embodiment.

Referring to FIG. 13, the method may include operation 1000 of forming a bit line extending in a first direction on a substrate, operation 2000 of forming a plurality of channel layers that extends in a second direction crossing the first direction on the bit line and that stands in a third direction perpendicular to the substrate, operation 3000 of forming a first cover insulating layer between the plurality of channel layers, operation 4000 of forming a word line between first cover insulating layers, operation 5000 of forming a second cover insulating layer by removing a portion of the first cover insulating layer disposed on one side of the word line and a portion of the word line, and operation 6000 of forming a second filling insulating layer on the word line. A thickness of the first cover insulating layer may be less than a thickness of the second cover insulating layer. A first permittivity of the first cover insulating layer may be greater than a second permittivity of the second cover insulating layer.

Operation 2000 may include operation 2100 of forming a plurality of channel layers, each having one end being in contact with the bit line, and operation 2200 of forming a first filling insulating layer between channel layers spaced apart from each other to have a preset height.

Operation 3000 may include operation 3100 of forming a first cover insulating layer that extends along a side surface of each of the channel layers and a top surface of the first filling insulating layer disposed between channel layers adjacent to each other, and operation 3200 of etching the first cover insulating layer being on the top surface of the first filling insulating layer, and the first cover insulating layer being on a top surface of each of the channel layers.

Operation 5000 may include operation 5100 of forming a sacrificial pattern layer configured to cover a top surface of another portion of the first cover insulating layer, a top surface of another portion of the word line, and the top surface of each of the channel layers, operation 5200 of etching one portion of the first cover insulating layer and one portion of the word line, operation 5300 of removing the sacrificial pattern layer, and operation 5400 of forming a second cover insulating layer in a space formed by removing the one portion of the first cover insulating layer and the one portion of the word line.

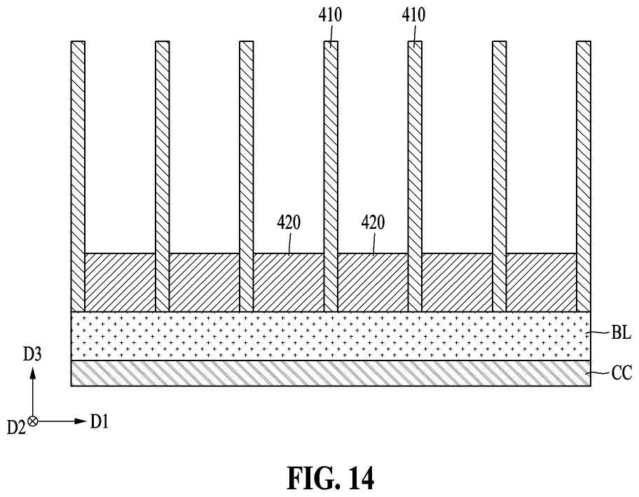

FIGS. 14 to 22 are cross-sectional views to describe a method of manufacturing a semiconductor device according to an embodiment.

Referring to FIG. 14, a substrate CC extending in a first direction D1 and a second direction D2 may be provided. A bit line BL may be disposed on the substrate CC. The bit line BL may extend lengthwise in the first direction D1. For example, a plurality of bit lines BL may be provided and spaced apart from each other in the second direction D2. A channel layer 410 may extend in the second direction D2 crossing the first direction D1. The channel layer 410 may stand in a third direction D3 perpendicular to the substrate CC. A plurality of channel layers 410 may be formed. One end of each of the channel layers 410 may be in contact with the bit line BL. The channel layers 410 may be spaced apart from each other by a predetermined distance. A first filling insulating layer 420 may be disposed between channel layers 410 spaced apart from each other. The first filling insulating layer 420 may be formed to have a preset height. A top surface of the first filling insulating layer 420 may be formed at a level lower than a top surface of the channel layer 410.

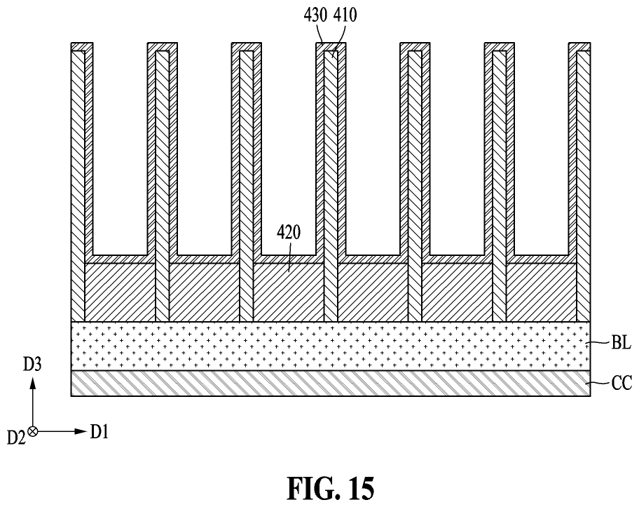

Referring to FIG. 15, a first cover insulating layer 430 may be formed between the plurality of channel layers 410. The first cover insulating layer 430 may extend along a side surface and a top surface of each of the channel layers 410 and a top surface of the first filling insulating layer 420 disposed between channel layers 410 adjacent to each other. The first cover insulating layer 430 may cover the side surface and the top surface of each of the channel layers 410. The first cover insulating layer 430 may cover the top surface of the first filling insulating layer 420.

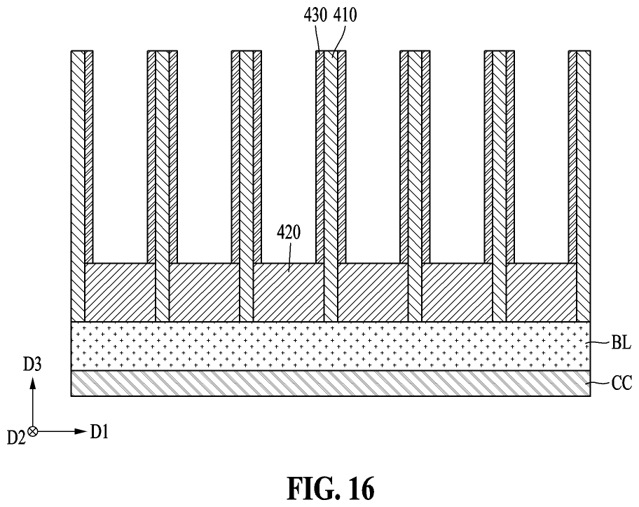

Referring to FIG. 16, the first cover insulating layer 430 on the top surface of the first filling insulating layer 420 may be etched. The first cover insulating layer 430 on the top surface of the channel layer 410 may be etched. Only the first cover insulating layer 430 on the side surface of the channel layer 410 may be left.

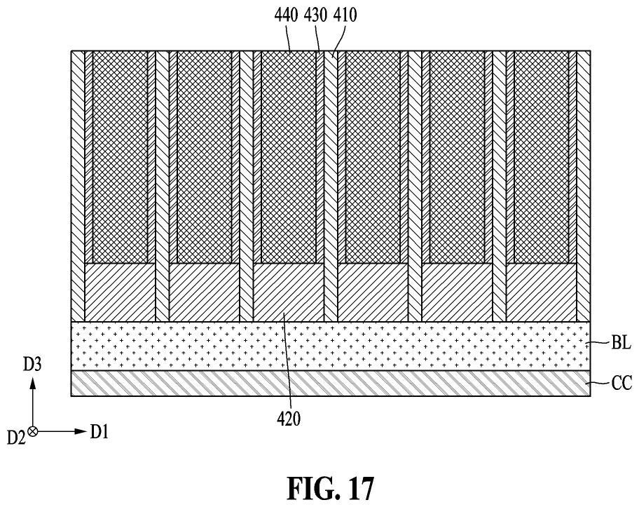

Referring to FIG. 17, a word line 440 may be formed between first cover insulating layers 430 facing each other. A space between the first cover insulating layers 430 facing each other may be filled with the word line 440.

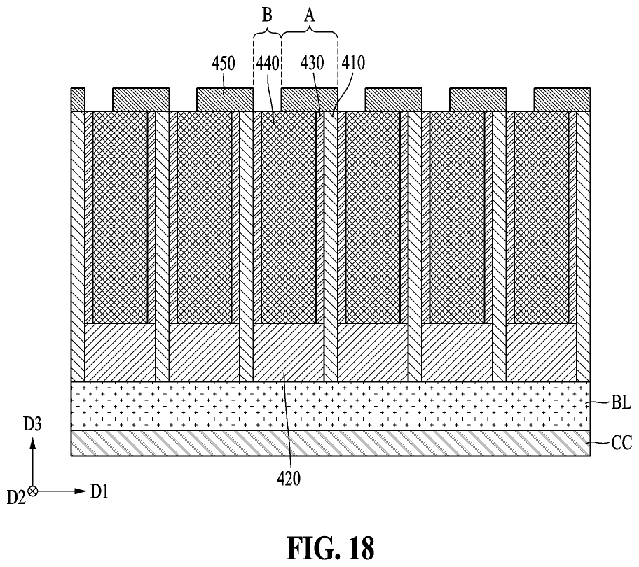

Referring to FIG. 18, a sacrificial pattern layer 450 may cover a top surface of another portion of the first cover insulating layer 430, a top surface of another portion of the word line 440, and the top surface of the channel layer 410. A first portion A of a gate region formed with the other portion of the first cover insulating layer 430, the other portion of the word line 440, and the channel layer 410 may be covered by the sacrificial pattern layer 450. A top surface of a second portion B of a gate region formed with one portion of the first cover insulating layer 430 and one portion of the word line 440 may be exposed. On the top surface of the second portion B of the gate region, a sacrificial pattern layer may not be disposed.

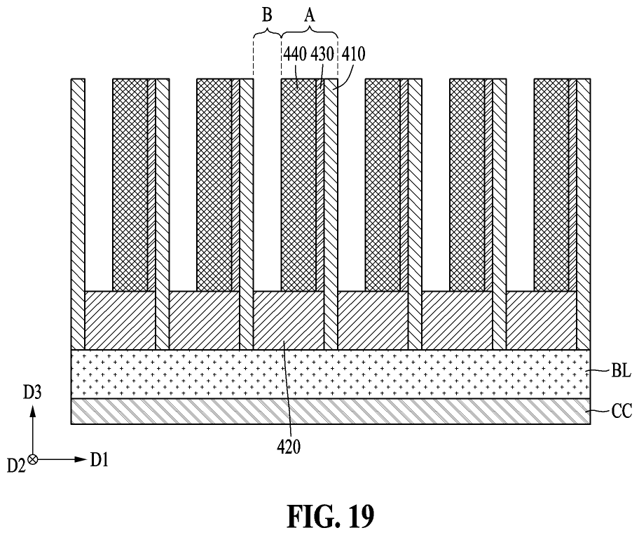

Referring to FIG. 19, the second portion B of the gate region formed with the one portion of the first cover insulating layer 430 and the one portion of the word line 440 may be etched. Subsequently, the sacrificial pattern layer 450 may be removed.

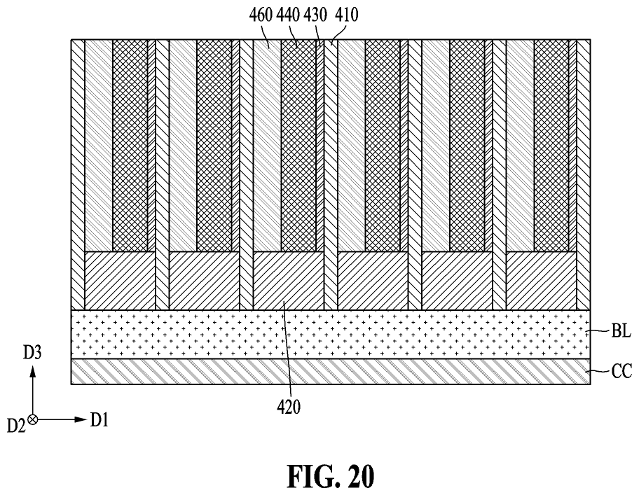

Referring to FIG. 20, a second cover insulating layer 460 may be formed in a space formed by removing the one portion of the first cover insulating layer 430 and the one portion of the word line 440. The space formed by removing the one portion of the first cover insulating layer 430 and the one portion of the word line 440 may be filled with the second cover insulating layer 460.

Alternatively, the space formed by removing the one portion of the first cover insulating layer 430 and the one portion of the word line 440 may not be filled with an additional material, and a subsequent process may be performed. Here, the space formed by removing the one portion of the first cover insulating layer 430 and the one portion of the word line 440 may be filled with air.

As the entire space formed by removing the one portion of the first cover insulating layer 430 and the one portion of the word line 440 is filled with the second cover insulating layer 460, a thickness of the second cover insulating layer 460 in the first direction D1 may be greater than a thickness of the first cover insulating layer 430 in the first direction D1. A second permittivity of the second cover insulating layer 460 may be less than a first permittivity of the first cover insulating layer 430.

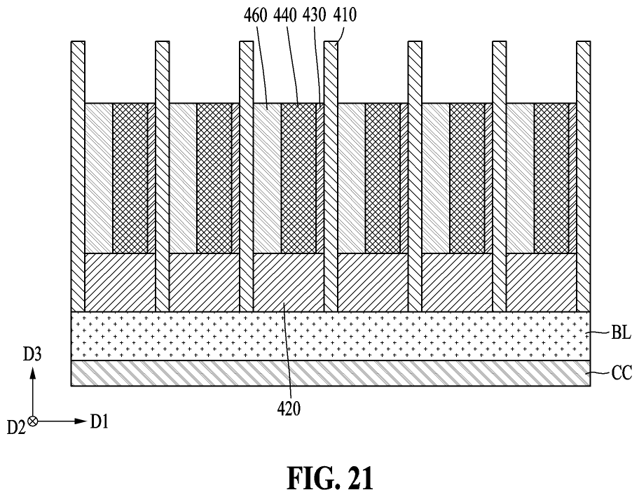

Referring to FIG. 21, an upper portion of each of the first cover insulating layer 430, the word line 440, and the second cover insulating layer 460 may be partially etched by a predetermined length in the third direction D3. The top surface of each of the first cover insulating layer 430, the word line 440, and the second cover insulating layer 460 may be formed at a lower level than the top surface of the channel layer 410.

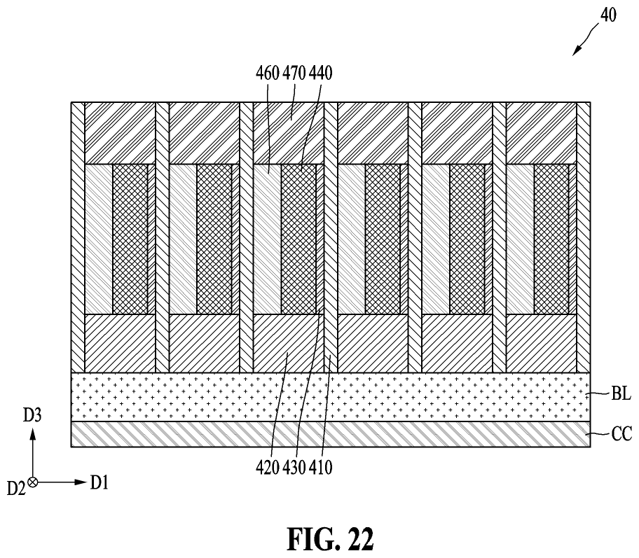

Referring to FIG. 22, a space formed by partially removing the upper portion of each of the first cover insulating layer 430, the word line 440, and the second cover insulating layer 460 may be filled with a second filling insulating layer 470. Accordingly, a semiconductor device 40 including a plurality of gate regions may be formed. One gate region may include the channel layer 410, the first cover insulating layer 430 in contact with the channel layer 410, the second cover insulating layer 460 spaced apart from the first cover insulating layer 430, and the word line 440 disposed between the first cover insulating layer 430 and the second cover insulating layer 460. A thickness of the first cover insulating layer 430 may be less than a thickness of the second cover insulating layer 460, and a permittivity of the first cover insulating layer 430 may be greater than a permittivity of the second cover insulating layer 460.

The semiconductor device and the method of manufacturing the semiconductor device according to embodiments may effectively prevent coupling between word lines.

In addition, the semiconductor device and the method of manufacturing the semiconductor device according to embodiments may enhance electrical characteristics and reliability of the semiconductor device.

While the embodiments are described with reference to drawings, it will be apparent to one of ordinary skill in the art that various alterations and modifications in form and details may be made in these embodiments without departing from the spirit and scope of the claims and their equivalents. For example, suitable results may be achieved if the described techniques are performed in a different order and/or if components in a described system, architecture, device, or circuit are combined in a different manner and/or replaced or supplemented by other components or their equivalents.

What is claimed is:

1. A semiconductor device comprising:
at least one bit line extending in a first direction on a substrate; and
at least one gate region on the at least one bit line,
wherein a first gate region comprises:
a first channel layer extending in a second direction perpendicular to the first direction and extending in a third direction perpendicular to the substrate;
a first word line on a side of the first channel layer;
a first cover insulating layer on a first side surface of the first word line facing the first channel layer; and
a second cover insulating layer on a second side surface of the first word line opposite the first side surface of the first word line,
wherein a thickness in the first direction of the first cover insulating layer is less than a thickness in the first direction of the second cover insulating layer.

2. The semiconductor device of claim 1, wherein a first permittivity of the first cover insulating layer is different from a second permittivity of the second cover insulating layer.

3. The semiconductor device of claim 2, wherein the first permittivity is greater than the second permittivity.

4. The semiconductor device of claim 1, wherein the first channel layer comprises silicon.

5. The semiconductor device of claim 1, wherein the first gate region further comprises a first filling insulating layer between the first word line and the at least one bit line.

6. The semiconductor device of claim 1, further comprising:
at least one silicon layer between the at least one gate region and the at least one bit line.

7. The semiconductor device of claim 1, wherein the first gate region further comprises a second filling insulating layer on the first word line.

8. The semiconductor device of claim 1, further comprising:
a second gate region on one side of the first gate region,
wherein the second gate region comprises:
a second channel layer in contact with the second cover insulating layer of the first gate region;
a second word line on a side of the second channel layer;
a third cover insulating layer on a first side surface of the second word line facing the second channel layer; and
a fourth cover insulating layer on a second side surface of the second word line opposite the first side surface of the second word line,
wherein a thickness in the first direction of the third cover insulating layer is less than a thickness in the first direction of the fourth cover insulating layer.

9. The semiconductor device of claim 8, wherein a third permittivity of the third cover insulating layer is greater than a fourth permittivity of the fourth cover insulating layer.

10. The semiconductor device of claim 8, wherein
a first voltage applied to the first word line is greater than a second voltage applied to the second word line, and
the first channel layer is controlled to be in an active state and the second channel layer is controlled to be in an inactive state.

11. A semiconductor device comprising:
a plurality of bit lines extending in a first direction on a substrate;
a plurality of gate isolation insulating layers that extend in a second direction perpendicular to the first direction on the plurality of bit lines and that extends in a third direction perpendicular to the substrate; and
a plurality of gate regions, each of the gate regions being between gate isolation insulating layers spaced apart from each other,
wherein a first gate region comprises:
a first channel layer extending along a side surface of one of the plurality of gate isolation insulating layers on two sides of the first gate region and on a top surface of a bit line being under the first gate region;
a first word line between a first and a second side surface of the first channel layer;
a first cover insulating layer between a first side surface of the first word line and a first side surface of the first channel layer; and
a second cover insulating layer between a second side surface of the first word line and a second side surface of the first channel layer,
wherein a thickness of the first cover insulating layer is less than a thickness of the second cover insulating layer.

12. The semiconductor device of claim 11, wherein a first permittivity of the first cover insulating layer is different from a second permittivity of the second cover insulating layer.

13. The semiconductor device of claim 12, wherein the first permittivity is greater than the second permittivity.

14. The semiconductor device of claim 11, wherein the first gate region further comprises a first filling insulating layer on the first word line.

15. The semiconductor device of claim 11, wherein the first channel layer comprises an oxide semiconductor.

16. A method of manufacturing a semiconductor device, the method comprising:
forming a bit line extending in a first direction on a substrate;
forming a plurality of channel layers that extend in a second direction perpendicular to the first direction on the bit line and in a third direction perpendicular to the substrate;
forming a first cover insulating layer between the plurality of channel layers;
forming a word line between sidewalls of the first cover insulating layer; and
forming a second cover insulating layer on an exposed sidewall of the word line after removing a portion of the first cover insulating layer on one side of the word line and removing a portion of the word line,
wherein a thickness of the first cover insulating layer is less than a thickness of the second cover insulating layer in the first direction.

17. The method of claim 16, wherein the forming of the plurality of channel layers comprises:
forming a plurality of channel layers, each having one end in contact with the bit line; and
forming a first filling insulating layer between channel layers spaced apart from each other, wherein a height of the first filling insulating layer is less than a height of one of the plurality of channel layers with respect to the substrate.

18. The method of claim 17, wherein the forming of the first cover insulating layer comprises:
forming an initial first cover insulating layer that extends along a side surface of each of the channel layers and a top surface of the first filling insulating layer between channel layers; and
etching the initial first cover insulating layer directly on the top surface of the first filling insulating layer and the first cover insulating layer directly on a top surface of each of the channel layers to form the first cover insulating layer.

19. The method of claim 18, wherein the forming of the second cover insulating layer comprises:
forming a sacrificial pattern layer configured to at least partially cover a top surface of the first cover insulating layer, a top surface of the word line, and the top surface of at least one of the plurality of the channel layers;
etching one portion of the first cover insulating layer and one portion of the word line;
removing the sacrificial pattern layer; and
forming a second cover insulating layer in a space formed by removing the one portion of the first cover insulating layer and removing the one portion of the word line,
wherein a first permittivity of the first cover insulating layer is greater than a second permittivity of the second cover insulating layer.

20. The method of claim 19, further comprising:
forming a second filling insulating layer on the word line.
